(19) United States
(12) Patent Application Publication
(10) Pub. No.: US 2016/0079172 A1
(43) Pub. Date: Mar. 17, 2016

(54) ADHESION LAYER FOR INTERCONNECT STRUCTURE

(71) Applicant: International Business Machines Corporation, Armonk, NY (US)

(72) Inventors: Chih-Chao Yang, Glenmont, NY (US); Wei Lin, Albany, NY (US); Terry A. Spooner, Clifton Park, NY (US); Oscar van der Straten, Guilderland Center, NY (US)

(21) Appl. No.: 14/488,446

(22) Filed: Sep. 17, 2014

(51) Int. Cl. H01L 23/532; H01L 21/768

(52) U.S. Cl. CPC H01L 23/53238; H01L 21/7685; H01L 21/76841

(57) ABSTRACT

Alternative methods of fabricating an interconnect structure having an adhesion layer, wherein the surfaces of the adhesion layer may be altered to correspond to the materials that are adhered to that surface.

### BACKGROUND

The present disclosure relates to a semiconductor structure and a method of fabricating the same. More particularly, the present disclosure relates to an interconnect structure including an enhanced diffusion barrier in which a metal nitride liner component of the diffusion barrier is formed in-situ. The present disclosure also provides methods of forming such an interconnect structure.

Generally, semiconductor devices include a plurality of circuit elements fabricated on a semiconductor substrate that form an integrated circuit (IC). A complex network of signal paths will normally be routed to connect the circuit elements distributed on the surface of the substrate. Efficient routing of these signals across the device requires formation of multilevel or multilayered schemes, such as, for example, single or dual damascene wiring structures. The wiring structure typically includes copper, Cu, or a Cu alloy, since Cu-based interconnects provide higher speed signal transmission between large numbers of transistors on a complex semiconductor chip as compared with aluminum-based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “crosstalk”) can be achieved in today's IC product chips by embedding the metal lines and metal vias (e.g., conductive features) in an interconnect dielectric material having a dielectric constant of less than 4.0.

### BRIEF SUMMARY

An embodiment of the invention may include a method of forming an interconnect structure. The method may include forming at least one opening into an interconnect dielectric material. A metal diffusion barrier liner may be formed on the interconnect dielectric material, with a portion of the metal diffusion barrier liner located in the opening. An adhesion layer having substantially the same crystal lattice structure as the metal diffusion barrier liner may be formed on the metal diffusion barrier liner. Following the deposition of the adhesion layer, the crystal lattice of at least the top surface of the adhesion layer may be manipulated to be the same as a conductive material that will be subsequently formed on the adhesion layer.

Another embodiment of the invention may include a method of adhering a first crystalline structure to a second crystalline structure. The method may include forming an adhesion layer on the first crystalline structure, where the adhesion layer has substantially the same crystal lattices structure of the first crystalline structure. At least a top portion of the adhesion layer may be modified to be substantially similar to the crystalline structure of the second crystalline structure. The second crystalline structure may then be formed directly on the top surface of the adhesion layer.

Another embodiment of the invention may include a semiconductor structure having an interconnect dielectric material with at least one opening located therein. A conductive material may be located in the at least one opening, and is separated from the interconnect dielectric material by a metal diffusion barrier liner and an adhesion layer. The surface of the adhesion layer in contact with the metal diffusion barrier has substantially the same crystalline structure as the metal diffusion barrier. The surface of the adhesion layer in contact with the conductive material has substantially the same crystalline structure as the conductive material.

### BRIEF DESCRIPTION OF THE SEVERAL DRAWINGS

FIG. 1 is a cross section view depicting an interconnect dielectric material, according to an exemplary embodiment.

FIG. 2 is a cross section view depicting forming at least one opening into the interconnect dielectric material, according to an exemplary embodiment.

FIG. 3 is a cross section view depicting depositing a metal barrier liner on the interconnect dielectric material, according to an exemplary embodiment.

FIG. 4 is a cross section view depicting depositing an adhesion layer, according to an exemplary embodiment.

FIG. 5 is a cross section view depicting forming a second adhesion layer from the first adhesion layer, according to an exemplary embodiment.

FIG. 6 is a cross section view depicting depositing a conductive material and planarizing the structure, according to an exemplary embodiment.

FIG. 7 is a cross section view depicting an adhesion layer on a first crystalline layer, according to an exemplary embodiment.

FIG. 8 is a cross section view depicting modifying the surface of the adhesion layer, according to an exemplary embodiment.

FIG. 9 is a cross section view depicting forming a second crystalline structure on the adhesion layer, according to an exemplary embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

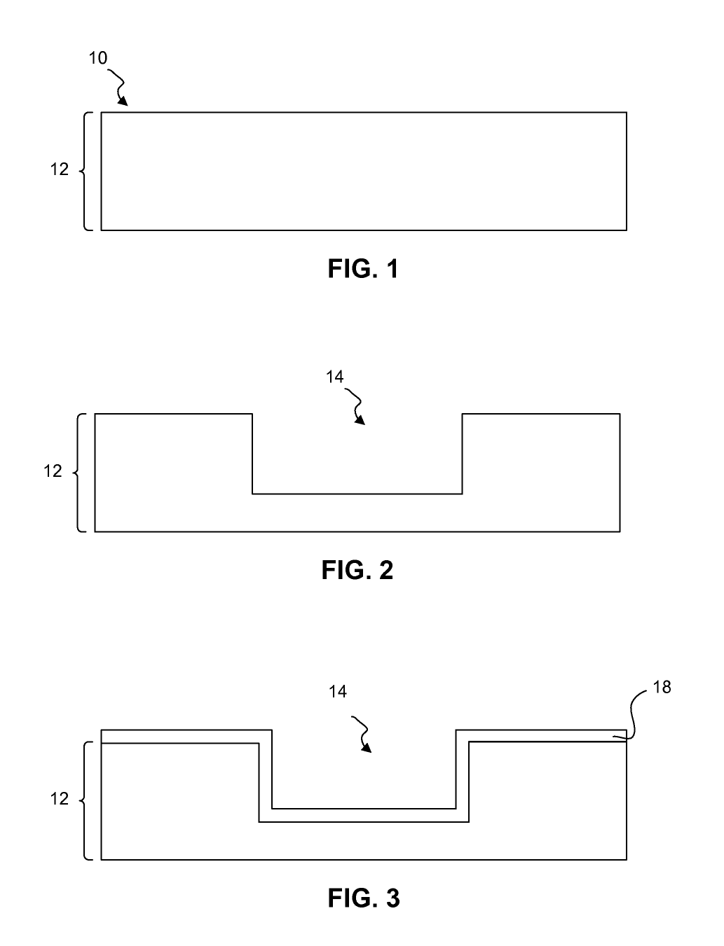

Semiconductor interconnect structures, composed of conductive and non-conductive components, may contain many various layers between the conductive portion and the non-conductive portion. These layers may be formed for different purposes, such as, for example limiting electromigration of the conductive material. However, intermediate layers may make it difficult to deposit subsequent metal layers due to various physical properties of the materials being incompatible. These limitations may be reduced by adding an intermediate adhesion layer between the incompatible materials. The adhesion layer may be selected, and subsequently modified, so the crystalline structure of each surface of the adhesion layer is sufficiently similar to the surfaces of the materials that it is adhering to. This may improve overall adhesion and deposition between the two incompatible materials. Reference is now made to FIGS. 1-6 which illustrate the processing steps employed in an embodiment of the present disclosure.

Referring now to FIG. 1, an initial structure 10 that comprises an interconnect dielectric material 12 is shown. The interconnect dielectric material 12 may be located upon a substrate (not shown). The substrate may comprise a semiconducting material, an insulating material, a conductive material or any combination thereof. When the substrate is comprised of a semiconducting material, any material having semiconductor properties such as, for example, Si, SiGe, SiGeC, SiC, Ge alloys, GaAs, InAs, InP and other III/V or II/VI compound semiconductors, may be used. In addition to these listed types of semiconducting materials, the substrate may be a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or any combination thereof including multilayers. When the substrate comprises a semiconducting material, one or more semiconductor devices such as, for example, complementary metal oxide semiconductor (CMOS) devices can be fabricated thereon. When the substrate comprises a combination of an insulating material and a conductive material, the substrate may represent an underlying interconnect level of a multilayered interconnect structure.

The interconnect dielectric material 12 that is employed in the present disclosure may comprise any interlevel or intralevel dielectric material, including inorganic dielectrics or organic dielectrics. In one embodiment, the interconnect dielectric material 12 may be non-porous. In another embodiment, the interconnect dielectric material 12 may be porous. Some examples of suitable dielectrics that can be used as the interconnect dielectric material 12 include, but are not limited to, SiO₂, silsesquioxanes, C doped oxides (i.e., organosilicates) that include atoms of Si, C, 0 and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The interconnect dielectric material 12 may have a dielectric constant that is about 4.0 or less, and preferably a dielectric constant of about 2.8 or less. All dielectric constants mentioned herein are relative to a vacuum, unless otherwise noted. These dielectrics generally have a lower parasitic cross talk as compared with dielectric materials that have a higher dielectric constant than 4.0. The thickness of the interconnect dielectric material 12 may vary depending upon the type of interconnect dielectric material used as well as the exact number of layers within the interconnect dielectric material 12. In an embodiment, the interconnect dielectric material 12 may have a thickness from 50 nm to 1000 nm.

Although not depicted in FIG. 1, a hard mask (not shown) may be formed on at least a portion of an upper surface of the interconnect dielectric material 12. When present, the hard mask can include an oxide, a nitride, an ox nitride or any multilayered combination thereof. In an embodiment, the hard mask may be an oxide such as silicon dioxide, while in another embodiment the hard mask may be a nitride such as silicon nitride.

The hard mask may be formed utilizing a conventional deposition process including, for example, chemical vapor deposition (CVD), plasma enhanced chemical vapor deposition (PECVD), chemical solution deposition, evaporation, and physical vapor deposition (PVD). Alternatively, the hard mask may be formed by one of thermal oxidation, and thermal nitridation.

The thickness of the hard mask employed in the present disclosure may vary depending on the material of the hard mask itself as well as the techniques used in forming the same. In an embodiment, the hard mask has a thickness from 5 nm to 100 nm, with a thickness from 10 nm to 80 nm being even more typical.

Referring now to FIG. 2, at least one opening 14 may be formed into the hard mask (not shown), if present, and into the interconnect dielectric material 12 utilizing lithography and etching. When the hard mask is not present, the at least one opening 14 is formed only into the interconnect dielectric material 12. The lithographic process may include: forming a photoresist layer (not shown) directly on the hard mask, if present, or directly on the interconnect dielectric material 12, if the hard mask is not present; exposing the photoresist to a desired pattern of radiation; and developing the exposed photoresist utilizing a conventional resist developer. The etching process may include a dry etching process (such as, for example, reactive ion etching, ion beam etching, plasma etching or laser ablation), and/or a wet chemical etching process. In an embodiment, the etching process may include a first pattern transfer step in which the pattern provided to the photoresist is transferred to the hard mask, the patterned photoresist is then removed by an ashing step, and thereafter, a second pattern transfer step is used to transfer the pattern from the patterned hard mask into the underlying interconnect dielectric material 12.

The depth of the at least one opening 14 that is formed into the interconnect dielectric material 12 (measured from the upper surface of the interconnect dielectric material 12 to the bottom surface of the at least one opening 14) may vary. In an embodiment, the at least one opening 14 may extend entirely through the interconnect dielectric material 12. In another embodiment, the at least one opening 14 stops within the interconnect dielectric material 12 itself. In yet another embodiment, different depth openings can be formed into the interconnect dielectric material 12.

The at least one opening 14 may be a via opening, a line opening, and/or a combined via/line opening. In an embodiment in which a combined via/line opening is formed, a via opening may be formed first and then a line opening may be formed atop and in contact with the via opening. In another embodiment in which a combined via/line opening is formed, a line opening may be formed first and then a via opening may be formed atop and in contact with the line opening.

In FIG. 2, and by way of an example, the at least one opening 14 is shown as a line opening. It is noted that although the drawings illustrate a single opening, the present disclosure is not limited to forming only one opening into the interconnect dielectric material 12. Instead, a plurality of openings may be formed. When a plurality of openings are formed, each opening may be a line opening, a via opening, a combined via/line opening or any combination thereof.

When a via or line is formed, a single damascene process (including the above mentioned lithography and etching steps) may be employed. When a combined via/line is formed a dual damascene process (including at least one iteration of the above mentioned lithography and etching steps) may be employed.

In an embodiment, the hard mask that is formed atop the interconnect dielectric material 12 can be removed from the structure after the at least one opening 14 is formed. The removal of the hard mask, which is also patterned, may be achieved by utilizing a conventional planarization process such as, for example, chemical mechanical planarization (CMP). In another embodiment, the patterned hard mask may remain on the upper horizontal surface of the interconnect dielectric material 12. The patterned hard mask may then be removed during a subsequent planarization step.

Referring now to FIG. 3, a metal diffusion barrier liner 18 may be formed on the dielectric material 12. The metal diffusion barrier liner 18 may be composed of a metal such as, but not limited to, Ta, Ti, Ru, RuTa, Co and W, and nitrides thereof. In an embodiment, the metal diffusion barrier liner 18 may be composed of TaN. The metal diffusion barrier liner 18 may be formed using a conventional deposition process including, for example, chemical vapor deposition (CVD), plasma enhanced chemical vapor deposition (PECVD), atomic layer deposition (ALD), physical vapor deposition (PVD), sputtering, chemical solution deposition and plating.

The thickness of the metal diffusion barrier liner 18 may vary depending on the deposition process used as well as the material employed. In an embodiment, the metal diffusion barrier liner 20 may have a thickness from 2 nm to 50 nm, and preferably a thickness from 5 nm to 20 nm. In an embodiment, the diffusion barrier liner 18 may be continuously present, i.e., without no apparent breaks in the liners, in at least the at least one opening 14 of the structure.

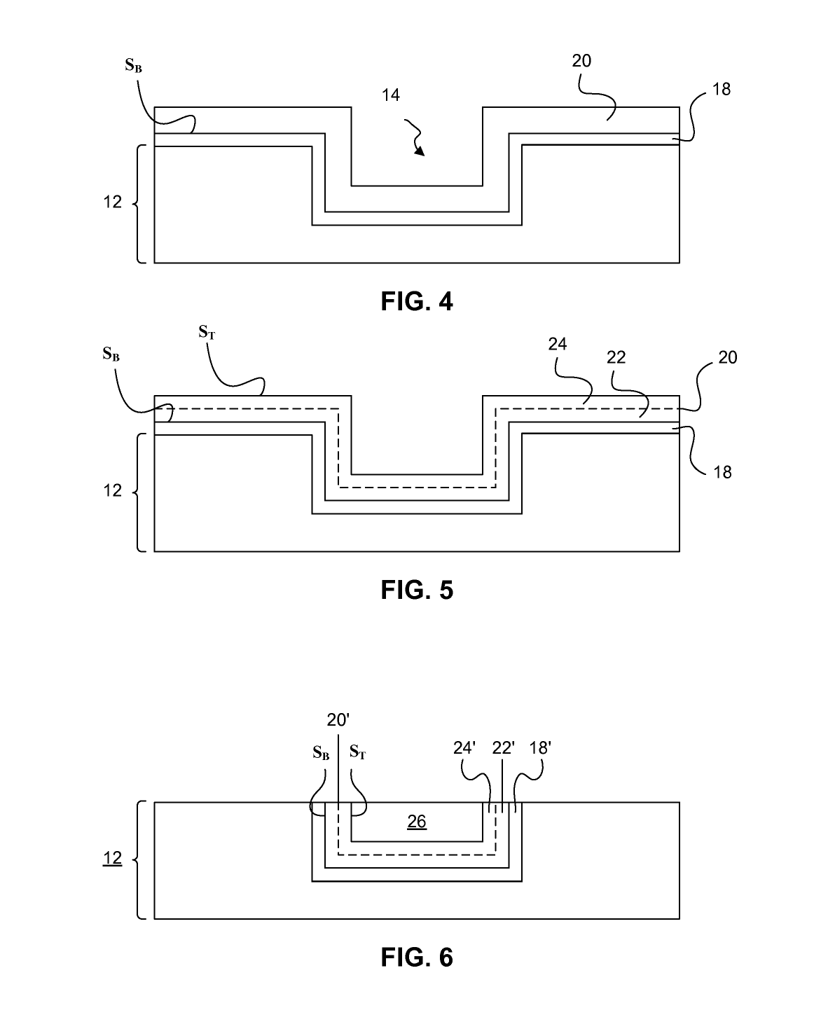

Referring now to FIG. 4, an adhesion layer 20 may be deposited on the metal diffusion barrier layer 18. The adhesion layer 20 may have a base surface S_{B} directly in contact with the metal diffusion barrier layer 18. The adhesion layer 20 is selected such that the crystalline structure of the adhesion layer 20 is the same as the crystalline structure of the metal diffusion barrier layer 18. This may allow the atomic structure of the adjoining materials to be better aligned, and thus create a stronger bond between the two materials due to a better crystal lattice fit. In an embodiment, TaN may be used for the diffusion barrier layer 18, while material having a hexagonal close-packed (HCP) crystalline structure, such as, for example, cobalt, may be used as the adhesion layer 20. The adhesion layer 20 may be formed by a deposition process including, for example, chemical vapor deposition (CVD), plasma enhanced chemical vapor deposition (PECVD), atomic layer deposition (ALD), physical vapor deposition (PVD), sputtering, chemical solution deposition and plating. After deposition, the adhesion layer 20 may be comprised of a single layer of a single material.

Referring now to FIG. 5, an exposed portion of adhesion layer 24 is modified in-situ to form a different lattice structure from the one originally present in the adhesion layer 20, which may still be present in the buried portion of adhesion layer 22. The exposed portion of adhesion layer 24 may have an exposed a top surface S_{T}, where the top surface S_{T} may have a different lattice structure as the base surface S_{B}. In an example embodiment, the exposed portion of adhesion layer 24 and the top surface S_{T} may be modified to a face centered cubic (FCC) crystalline structure, while the buried portion of adhesion layer 22 and the base surface S_{B} maintain their original HCP crystalline structure. The lattice structure of the exposed portion of adhesion layer 24 may be selected to match a lattice structure of a conductive material that may be subsequently formed on the top surface S_{T} of the exposed portion of adhesion layer 24. This may allow the atomic structures of the adjoining materials to be better aligned, and thus create a stronger bond between the two materials due to better crystal lattice fit.

The exposed portion of adhesion layer 24 may modified from the preexisting adhesion layer 20 by performing any type of process that may change the crystal lattice such as, for example, a thermal anneal or chemical doping. The modification process changes the crystal structure of the exposed portion of adhesion layer 24 and the top surface S_{T}, and creates an adhesion layer 20 where with different crystal lattice structures on the top surface S_{T} and the bottom surface S_{B}. Following the processing of the adhesion layer 20 the exposed portion of adhesion layer 24 is defined by a layer where the majority of the material has a different crystalline structure than the buried portion of adhesion layer 22, which possesses the original crystalline structure from depositing the adhesion layer 20. This transition is illustrated by the dotted line in FIG. 5. In such an embodiment, the process may produce chemical changes in the exposed portion of adhesion layer 24 (e.g. the addition of molecules to the lattice).

In an embodiment, nitrogen may be introduced into the adhesion layer 20 by plasma treatment or thermal treatment to produce a metal nitride having the chemical formula MₓN, where x is in the range of 0 to 1, and M is any suitable adhesion metal such as, for example, cobalt, ruthenium, tantalum, titanium or tungsten. The nitrogen may be introduced using nitrogen-containing molecules such as N₂, NH₃, NH₄, NO, and NHₓ, wherein x is between is in the range of 0 to 1. In an embodiment, the adhesion layer 20 may be composed of cobalt and may be adhered to the diffusion barrier layer 18, which may be composed of TaN. Surface nitridation via plasma treatment may be performed to create the exposed portion of adhesion layer 24 from a top portion of the adhesion layer 20 by converting cobalt to cobalt nitride, and thus change the crystalline structure from hexagonal close packed (HCP) to front centered cubic (FCC). This may allow for better adhesion with conductive materials that have a FCC crystalline structure such as, for example, copper. In another embodiment, the process may produce conformational changes in the adhesion layer 20 through mechanical, electrical, chemical, thermal treatment, chemical doping or any other suitable process.

Referring now to FIG. 6, a conductive material may be formed in the at least one opening 14 and the subsequent structure may be planarized. In FIG. 6, reference numeral 26 denotes the planarized conductive material, reference numeral 24′ denotes the planarized exposed portion of adhesion layer which is now U-shaped, reference numeral 22′ denotes the planarized buried portion of adhesion layer which is also now U-shaped, reference numeral 20′ denotes the planarized adhesion layer which is also now U-shaped, and reference numeral 18′ denotes the planarized barrier layer which is also now U-shaped. FIG. 6 shows an embodiment in which an upper surface of each of the planarized conductive material 26, the planarized adhesion layer 20′ and the planarized barrier layer 18′ layer may be co-planar with an upper surface of the interconnect dielectric material 12. In another embodiment, one or more layers may extend beyond, or be located above, atop surface of the interconnect dielectric material 12.

The structure shown in FIG. 6 may be formed by first depositing a layer of conductive material (not shown) atop the exposed portion of adhesion layer 24. In an embodiment, the layer of conductive material may completely fill the remaining portion of the at least one opening 14 and may extend above the at least one opening 14 onto the top surface of the dielectric material 12. The layer of conductive material may be composed of polySi, SiGe, a conductive metal, an alloy comprising at least one conductive metal, a conductive metal silicide or combinations thereof. In an embodiment, the layer of conductive material may be a conductive metal such as Cu, W or Al. In another embodiment, the layer of conductive material may be composed of Cu or a Cu alloy such as AlCu.

The layer of conductive material may be formed by any conventional deposition process including chemical vapor deposition (CVD), plasma enhanced chemical vapor deposition (PECVD), sputtering, chemical solution deposition or plating that fills the at least one opening 14 from the bottom upwards can be used. In an embodiment, the conductive material is formed utilizing a bottom-up plating process.

After depositing the conductive material, a planarization process such as, for example, chemical mechanical polishing (CMP) and/or grinding, may be employed to remove portions of the layer of the conductive material, the exposed portion of adhesion layer 24, the adhesion layer 20, and the barrier layer 18 from atop the horizontal surface of the interconnect dielectric material 12. In an embodiment in which a patterned hard mask is present, the planarization process may also be used to remove the patterned hard mask from the structure.

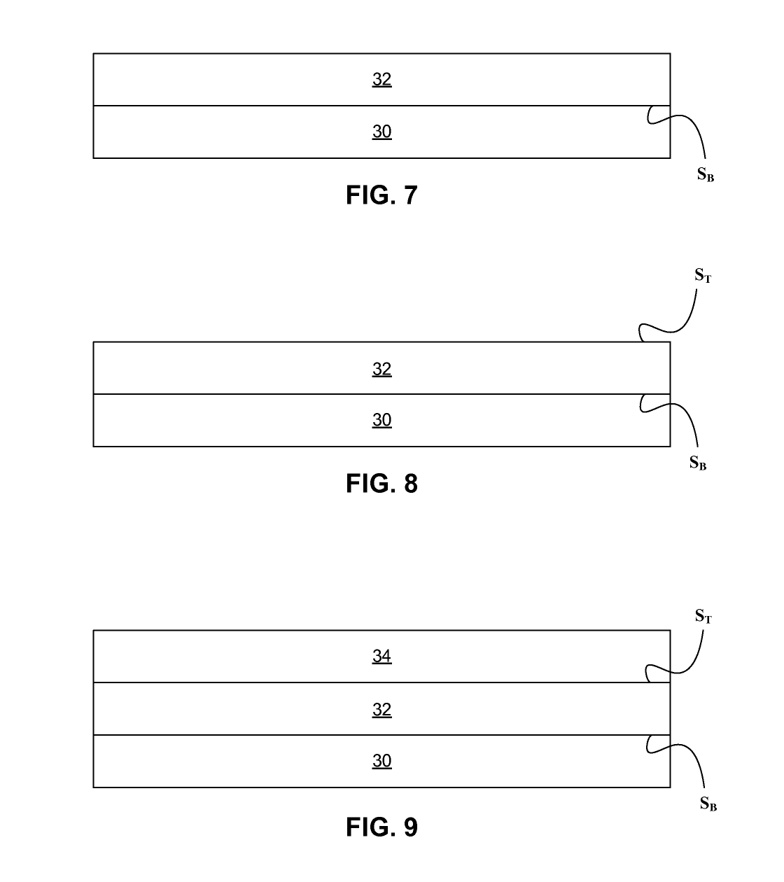

Reference is now made to FIGS. 7-9, which illustrate the basic adhesion principles that are employed in an embodiment of the present disclosure.

Referring to FIG. 7, an adhesion layer 32 is formed on a first crystalline layer 30. The adhesion layer 32 has a base surface S_{B} directly in contact with the first crystalline layer 30. The adhesion layer 32 is selected such that the crystalline structure of the adhesion layer 32 is the same as the crystalline structure of the first crystalline layer 30. This may allow the atomic of the adjoining materials to be better aligned, and thus create a stronger bond between the two materials due to a better crystal lattice fit. When determining proper materials for the adhesion layer 32, the first crystalline layer 30 may match have the same Bravais lattice structure of the adhesion layer 32 such as, for example, the adhesion layer 32 and the first crystalline layer 30 may both be an HCP lattice structure. The adhesion layer 32 may be formed by a deposition process including, for example, chemical vapor deposition (CVD), plasma enhanced chemical vapor deposition (PECVD), atomic layer deposition (ALD), physical vapor deposition (PVD), sputtering, chemical solution deposition and plating.

Referring now to FIG. 8, the adhesion layer 32 may be modified to change the crystalline structure of a top surface S_{T}. The adhesion layer 32 may be modified to so the top surface S_{T} may have a different lattice structure as the base surface S_{B}. The lattice structure of the top surface S_{T} may be selected to match the lattice structure of a second crystalline layer 34 (FIG. 9) that may be subsequently formed on the top surface S_{T} of the adhesion layer 32. Manipulating the top surface S_{T} of the adhesion layer 32 to have the same crystalline structure as the second crystalline layer 34, may allow the atomic structure of the adjoining materials to be better aligned, and thus create a stronger bond between the two materials due to a better crystal lattice fit. The crystalline structure of the top surface S_{T} may be modified through mechanical, electrical, chemical, thermal treatment, chemical doping or any other process suitable to create a change in the crystalline structure. Following the modification of the adhesion layer, the transition of the crystal lattice structure from the structure exhibited on the base surface S_{B} to the structure exhibited on the top surface S_{T} may be gradual or abrupt.

Referring now to FIG. 9, the second crystalline layer 34 may be formed atop the adhesion layer 32. In the previous step, the adhesion layer 32 may be altered to create a top surface S_{T} having a similar crystalline structure to the second crystalline layer 34, which may allow the atomic structure of the adjoining materials to be better aligned, and thus create a stronger bond between the two materials due to a better crystal lattice fit. When determining proper materials for the second crystalline layer 34, the top surface S_{T} may match the Bravais lattice structure of the second crystalline layer 34 such as, for example, the second crystalline layer 34 and the top surface S_{T} may both be an FCC lattice structure. The second crystalline layer 34 may be formed by a deposition process including, for example, chemical vapor deposition (CVD), plasma enhanced chemical vapor deposition (PECVD), atomic layer deposition (ALD), physical vapor deposition (PVD), sputtering, chemical solution deposition and plating.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

1. A method of forming an interconnect structure, the method comprising:
forming at least one opening into an interconnect dielectric material;
forming a metal diffusion barrier liner on the interconnect dielectric material, wherein at least a portion of the metal diffusion barrier liner is inside of at least one opening, and wherein the metal diffusion barrier liner comprises a second metal;
forming an adhesion layer on the metal diffusion barrier liner, wherein the adhesion barrier has a sufficiently similar lattice structure as the metal diffusion barrier liner, wherein the adhesion layer comprises a first metal, and wherein the first metal is different from the second metal;
modifying the lattice structure on at least an exposed surface of the adhesion layer to a lattice structure having a different orientation;
forming a conductive material on the adhesion layer, wherein the conductive material has the same lattice structure of the modified surface of the adhesion layer; and
removing the conductive material, the adhesion layer and the metal diffusion barrier liner that are located outside of the at least one opening.

2. The method of claim 1, wherein the lattice structures are Bravais lattice structures.

3. The method of claim 1, wherein modifying the lattice structure comprises changing the chemical composition of at least the exposed surface of the adhesion layer.

4. The method of claim 1, wherein modifying the lattice structure comprises thermal treatment of at least the exposed surface of the adhesion layer.

5. The method of claim 1, wherein the conductive material comprises copper.

6. The method of claim 1, wherein the metal diffusion barrier liner comprises tantalum nitride.

7. The method of claim 1, wherein the adhesion layer comprises cobalt.

8. The method of claim 7, wherein nitrogen is introduced into at least the surface of the adhesion layer to change the lattice structure.

9. A method of adhering a first crystalline structure to a second crystalline structure, the method comprising:
forming an adhesion layer on the first crystalline structure, wherein the adhesion layer comprises a first metal, wherein the first crystalline structure comprises a second metal, wherein the first metal and the second metal are different, and wherein the adhesion layer has substantially the same crystalline structure as the first crystalline structure;
modifying at least an exposed surface of the adhesion layer to change the crystalline structure of at least the exposed surface of the adhesion layer to be substantially similar to the crystalline structure of the second crystalline structure; and
forming the second crystalline structure on the adhesion layer.

10. The method of claim 9, wherein the crystalline structures are Bravais lattice structures.

11. The method of claim 9, wherein modifying at least an exposed surface of the adhesion layer comprises changing the chemical composition of at least the exposed surface of the adhesion layer.

12. The method of claim 9, wherein modifying at least an exposed surface of the adhesion layer comprises thermal treatment of at least the exposed surface of the adhesion layer.

13. The method of claim 9, wherein the second crystalline structure comprises copper.

14. The method of claim 9, wherein the first crystalline structure comprises tantalum nitride.

15. The method of claim 9, wherein the adhesion layer comprises cobalt.

16. The method of claim 15, wherein nitrogen is introduced into at least the surface of the adhesion layer to change the lattice structure.

17. A semiconductor structure comprising:
an interconnect dielectric material comprising at least one opening located therein;
a conductive material located within the at least one opening, the conductive material is separated from the interconnect dielectric material by a metal diffusion barrier liner and an adhesion layer, wherein the adhesion layer comprises a first metal, wherein the metal diffusion barrier liner comprises a second metal, and wherein the first metal is different from the second metal;
wherein a first surface of the adhesion layer is in contact with the metal diffusion barrier liner and has substantially the same crystalline structure as the metal diffusion barrier liner;
wherein a second surface of the adhesion layer is in contact with the conductive material and has substantially the same crystalline structure as the material diffusion barrier liner; and
wherein the first surface of the adhesion layer and the second surface of the adhesion layer have different crystalline structures.

18. The semiconductor structure of claim 17, wherein the conductive material comprises copper.

19. The semiconductor structure of claim 17, wherein the adhesion layer comprises cobalt.

20. The semiconductor structure of claim 17, wherein the metal diffusion barrier liner comprises tantalum nitride.
